(19) United States
(12) Patent Application Publication
(10) Pub. No.: US 2006/0276056 A1
(43) Pub. Date: Dec. 7, 2006

(54) Nanotube articles with adjustable electrical conductivity and methods of making the same

(75) Inventors: Jonathan W. Ward, Fairfax, VA (US); Thomas Rueckes, Rockport, MA (US); Brent M. Segal, Woburn, MA (US)

Correspondence Address: WILMER CUTLER PICKERING HALE AND DORR LLP, 60 STATE STREET, BOSTON, MA, 02109, US

(73) Assignee: Nantero, Inc., Woburn, MA (US)

(21) Appl. No.: 11/398,126

(22) Filed: Apr. 5, 2006

Related U.S. Application Data
(60) Provisional application No. 60/668,396, filed on Apr. 5, 2005.
(60) Provisional application No. 60/714,282, filed on Sep. 6, 2005.

(51) Int. Cl. D04H 1/00; H01L 21/00; D04H 3/00; D04H 5/00

(52) U.S. Cl. 438/800; 442/414; 442/415; 442/340; 442/341

(57) ABSTRACT

Nanotube articles having adjustable electrical conductivity, and methods of making the same. A patterned article includes conducting nanotubes that define a plurality of conductive pathways along the article, and also includes nanotubes of modified electrical conductivity. The modified nanotubes may electrically isolate the conducting nanotubes from other conductors. The nanotube segments may originally be semiconducting nanotubes, metallic nanotubes, nanotubes, single walled carbon nanotubes, multi-walled carbon nanotubes, or nanotubes entangled with nanotubes. The various segments may have different lengths and may include segments having a length shorter than the length of the article. A strapping material may be positioned to contact a portion of the plurality of nanotube segments. Such a strapping layer may also be used for making electrical contact to the nanotube fabric especially for electrical stitching to lower the overall resistance of the fabric.

### CROSS-REFERENCE TO RELATED APPLICATIONS

This application claims the benefit under 35 U.S.C. § 19(e) of the following applications, the entire contents of which are hereby incorporated by reference herein:

Patterned Nanoscopic Articles and Methods Of Making The Same (U.S. Provisional Patent Appln. No. 60/668,396), filed on Apr. 5, 2005; and

Encapsulation of Metal Lines Within Dielectric CNT Fabric (U.S. Provisional Patent Appln. No. 60/714,282), filed on Sep. 6, 2005.

This application is related to the following patent applications, which are assigned to the assignee of this application, and are hereby incorporated by reference in their entirety:

Patterned Nanoscopic Articles and Methods of Making Same (U.S. patent application Ser. No. 10/936,119), filed on Sep. 8, 2004;

Methods of Nanotube Films and Articles (U.S. Pat. No. 6,835,591), filed on Apr. 23, 2002; and

Non-Volatile Electromechanical Field Effect Devices and Circuits Using Same and Methods of Forming Same (U.S. patent application Ser. No. 10/864,186), filed on Jun. 9, 2004.

### BACKGROUND

1. Technical Field

This invention relates in general to the modification of the electrical conductivity of nanoscopic materials, films, fabrics, layers, and articles.

2. Discussion of Related Art

Nanotubes are used for electronic conductors and semiconductors as well as for light emitters, sensors, including biosensors, etc.

Individual carbon nanotubes may have segments which exhibit conducting properties and other segments which have semiconducting properties. See Chibotaru, L. F. et al., “Bend-induced gap in carbon nanotubes,” Phys. Rev., B 66, 161401 (R) (2002), the entire contents of which are hereby incorporated by reference herein. Investigators have reported that conducting tubes may be made to be electrically insulating by introduction of defects or functionalization, see Planck, N. O. V., et al., “Fluorination of Carbon Nanotubes in CF₄ Plasma,” Appl. Phys. Lett. 2002, Vol. 83 No. 12 2426-2428, the entire contents of which are hereby incorporated by reference herein. Ionization of carbon nanotubes also alters the electrical characteristics of the individual tubes.

### SUMMARY

The current invention generally relates to modifying the electrical conductivity properties of nanotube fabrics. More specifically, the invention relates to reversibly altering the electrical properties of electrically conducting nanotube fabrics to create sheets of insulating nanotube fabric, which can be patterned and/or positioned wherever needed. When desired, the conductivity of the insulating nanotube fabric can again be altered, to form an electrically conducting nanotube fabric. The electrical conductivity of a nanotube fabric, and in general of the nanotubes that make up that fabric, can be tunably adjusted within an extremely wide range, from near-ohmic to highly resistive.

Under one aspect, a method of modifying the electrical resistance of individual nanostructures within a layer of the nanostructures includes providing a layer of nanostructures, where the layer is characterized by an electrical resistance. The method also includes exposing the layer of nanostructures to a type and amount of reactive ions sufficient to increase the electrical resistance of the layer of nanostructures by a desired amount. The layer of nanostructures has a sufficiently low porosity to substantially expose each individual nanostructure within the layer to the reactive ions.

Under another aspect, exposure to the reactive ions increases the electrical resistance of substantially each individual nanostructure within the layer. Exposure to the reactive ions may increase the electrical resistance of the layer of nanostructures by a factor of at least 10. The layer of nanostructures may include a non-woven fabric of nanostructures. Each individual nanostructure within the layer may lie substantially parallel to a substrate. The nanostructures may include single-walled carbon nanotubes. The nanostructures may include multi-walled carbon nanotubes. The nanostructures may include nanowires. Heating the layer of nanostructures may reduce the electrical resistance of the layer of nanostructures.

Under another aspect, the method also includes depositing a patterned mask over a defined portion of the layer of nanostructures before exposing the layer to reactive ions. The defined portion of the layer may not be exposed to the reactive ions and its electrical resistance may not be increased. The defined portion of the layer may form an electrically conductive trace. Under another aspect, the reactive ions may be provided by at least one of CF₄, CHF₃, H₂, CH₄, SF₆, Ar, BCl₃, Cl₂, CCl₂F₂, SiCl₄, C₄F₈, HBr, and mixtures thereof. Under another aspect, providing the layer of nanostructures includes growing the nanostructures on a substrate. Under another aspect, providing the layer of nanostructures includes depositing pre-grown nanostructures on a substrate.

Under another aspect, a nanotube fabric of adjustable electrical resistance includes a non-woven fabric of nanotubes, where the non-woven fabric is characterized by an electrical resistance. Substantially each individual nanotube in the fabric is electrically resistive. The electrical resistance of substantially each individual nanotube in the fabric is increasable in response to reaction with a type and amount of reactive ions sufficient to increase the electrical resistance of the fabric by a desired amount. The electrical resistance of substantially each individual nanotube in the fabric is reducible in response to a period and temperature of heating sufficient to reduce the electrical resistance of the fabric by a desired amount.

Under another aspect, the non-woven fabric of nanotubes forms an electrical insulator. The electrical resistance of the fabric may be a function of a number of functional groups attached to substantially each individual nanotube of the fabric. Reaction of the fabric with reactive ions may at least partially functionalize substantially each individual nanotube of the fabric. Heating of the fabric may at least partially drive functional groups off of substantially each individual nanotube of the fabric. Heating of the fabric may reduce the electrical resistance of the fabric below about 10,000 Ω/square.

Under another aspect, the electrical resistance of the fabric is at least about 1 MΩ/square. Under another aspect, the electrical resistance of the fabric is at least about 1 TΩ/square. Substantially each individual nanotube of the fabric may have an electrical resistance of about 1 MΩ.

Under another aspect, a patterned nanotube fabric includes a non-woven fabric of nanotubes. The fabric has a first defined region, which includes nanotubes that substantially each individually are in a resistive state, and a second defined region, which includes nanotubes that substantially each individually are in a conductive state.

Under another aspect, the first defined region has an electrical resistance that is at least about 10 times greater than that of the second defined region. Under another aspect, the first defined region has an electrical resistance that is at least about 10⁶ times greater than that of the second defined region. The fabric may include at least one nanotube that has a relatively high resistance segment that overlaps the first defined region, and a relatively low resistance segment that overlaps the second defined region. The first defined region may form an electrical insulator. The second defined region may form an electrically conductive trace. The first defined region may electrically insulate the electrically conductive trace from at least one conductor. The nanotubes of the second region may form an electrical network of nanotubes that define a plurality of conductive pathways within the second defined region.

Under another aspect, the first region and second region touch each other along at least one border. Under another aspect, the first region and second region are substantially coplanar. The non-woven fabric of nanotubes may include substantially a monolayer of nanotubes. The non-woven fabric of nanotubes may be porous. The non-woven fabric of nanotubes may include substantially single-walled nanotubes. Under another aspect, a lithographically patterned strapping material contacts at least a portion of the second defined region. The substrate may be flexible. The substrate may include at least one of plastic, glass, silicon, silicon oxide, or silicon nitride.

Under another aspect, a circuit includes a first conductive electrode, and a second conductive electrode in spaced relation to the first electrode. The circuit also includes a non-woven nanotube fabric of nanotubes substantially to fill the volume between the first and second electrodes. Substantially each individual nanotube of the fabric is in an electrically resistive state.

Under one aspect, the fabric electrically insulates the first electrode from the second electrode. Under another aspect, the fabric substantially encapsulates the first and second electrodes. Under another aspect, the fabric forms an interlayer dielectric between the first and second electrodes.

Under another aspect, a method of forming a patterned nanotube fabric includes providing a substrate having a top surface, the top surface having a patterned trench. The method also includes providing a non-woven nanotube fabric over the substrate. The fabric has a first portion that substantially fills the volume defined by the patterned trench, and a second portion that substantially covers the rest of the top surface of the substrate. The method also includes substantially removing the second portion of the fabric, to leave the first portions of the non-woven nanotube fabric substantially filling the volume defined by the trench. Removing the second portion of the fabric may include mechanically polishing the top surface of the substrate. Removing the second portion of the fabric may include spraying a solvent over the top surface of the substrate. Under another aspect, the method includes exposing the fabric to reactive ions of a type and amount sufficient to increase the electrical conductivity of the fabric by a desired amount.

The described methods for patterning and modifying the electrical conductivity of nanotubes, nanofabrics, and nanowires, are compatible with typical semiconductor processing.

The term “nanowire” as used herein is intended to describe a nanoscale particle typically of high aspect ratio, regardless of the composition or electrical conductivity of the material.

The term “nanotube” or “nanotubes” as used herein is intended to mean carbon nanotubes. Carbon nanotubes may be pristine, functionalized, or they may be filled with other material, e.g., nanowire material.

The term “monolayer fabric” as used herein is intended to mean a non-woven fabric of nanotubes or a non-woven fabric of nanotubes and nanowires which is primarily one layer thick.

### BRIEF DESCRIPTION OF THE DRAWING

In the Drawing,

FIGS. 1A-1B are micrographs of nanotube fabrics having patterned conducting and insulating regions according to certain embodiments;

FIG. 2 is a micrograph of a nanotube fabric having an insulating region and an electrically conducting nanotube trace according to certain embodiments;

FIG. 3 illustrates steps for fabricating a patterned nanotube fabric in accordance with certain embodiments;

FIGS. 4A-4D illustrate exemplary architectures for structures according to certain embodiments;

FIG. 5 illustrates steps for fabricating regions of thick nanotube fabric in accordance with certain embodiments;

FIG. 6 is a micrograph of a thick nanotube fabric fabricated in accordance with certain embodiments;

FIG. 7 illustrates steps for fabricating regions of nanotube fabric in accordance with certain embodiments; and

FIG. 8 is a micrograph of a region of nanotube fabric fabricated in accordance with certain embodiments.

### DETAILED DESCRIPTION

Controllably adjusting the electrical conductivity of nanotube fabrics allows for the fabrication of patterned nanotube articles, having a specified conductivity, which are useful in many electronic applications. Specifically, a patterned nanotube article can be controllably converted from being an electrical conductor, e.g., an electrical trace, to being an electrical insulator, e.g., an interlayer dielectric. The article's conductivity can be selected within a very wide range, so that the article can be converted from a low resistance, near-ohmic conductor, to a high resistance insulator. Moreover, the changes made to the article's conductivity are controllably reversible, so that the article can be programmably converted from being highly conductive, to highly resistive, to highly conductive, or to any desired resistivity in between.

Methods for adjusting the conductivity of a nanotube article or fabric are based on the controlled reaction of the article with reactive ions, typically during the controlled exposure to reactive gases in plasma. This reaction can take place, e.g., in a Reactive Ion Etch (RIE) device/chamber. The article's exposure time to the reactive ions, the kind and concentration of reactive ions in the plasma, gas flow rates, and other parameters are adjusted so that the article reacts with the ions to a controlled extent. The extent of reaction defines the resulting conductivity of the article. In some embodiments, the ions partially or completely functionalize the nanotubes of the article, and the extent of functionalization defines the resulting conductivity of the article. The article or fabric can be patterned so that the conductivity is modified only for desired portions of the article or fabric, e.g., using conventional photolithography. The reaction of the fabric or article is also controllably reversible, e.g., by annealing the article to drive off the functionalizing groups, or by otherwise reversing the earlier reaction, the initial state of the nanotube article or fabric can be substantially recovered. Or, the reaction can be only partially reversed, to provide a nanotube article or fabric having an intermediate electrical conductivity. In addition, the porosity of the nanotube fabric can be selected to provide a suitable initial conductivity, as well as to allow the majority of the nanotubes in the fabric to be controllably reacted, thus maximizing the adjustability of the fabric conductivity. Methods of controlling the electrical conductivity of a nanotube article or fabric are described in greater detail below.

It should be noted that although the following embodiments relate to the conversion of the electrical properties of nanotubes, these embodiments are not limited only to carbon nanotubes. Rather, the described methods may also be applied to the alteration of electrical properties of nanoclusters and nanowires, such as silicon nanowires, or other kinds of nanotubes. Nanotubes, nanowires and nanoclusters are known in the art.

Nanotube articles or fabrics of adjustable conductivity can be used in a wide range of electronic applications. For example, an insulating nanotube article can be used to encapsulate an electrical conductor, or as an insulating spacer to prevent electrical coupling between two electrical elements. Or, an insulating nanotube article can be used as an interlayer dielectric layer. The dielectric constant of an insulating nanotube article or fabric is expected to be very low compared with other dielectrics that are commonly used as interlayer dielectric layers. This low dielectric constant will allow for reduced capacitance coupling between two or more interconnect lines, which would otherwise increase the delay of interconnect lines and degrade the operating characteristics of the interconnects. In general, insulating nanotube articles or fabrics are useful wherever insulators are useful.

Methods for converting and patterning nanoscale articles and nanoscale features are disclosed in which nanotubes are placed on or grown onto a surface and the electrical characteristics of at least some of the resulting nanofabric is changed from conducting to insulating. Electrical characteristics of the entire fabric or portions of the fabric can be altered. Such patterning of nanofabric articles is done by converting portions of the nanofabric articles to an electrically insulating state (or other desired state of electrical conductivity) while other portions are left electrically conducting. For example, an initial conducting nanotube fabric with a resistance value ranging from about 0.1-100 kΩ/square, depending on the thickness of the fabric, can be converted to an insulating fabric with a resistance greater than 1 MΩ/square, greater than 100 MΩ/square, greater than 1 GΩ/square, and even up to or exceeding 1 TΩ/square. An individual conducting nanotube has an initial minimum resistance of about 6.5 kΩ. This nanotube can be converted to an insulating nanotube, having a resistance of greater than 1 MΩ, depending upon the extent by which its resistance is adjusted; intermediate resistances can also be achieved. In general, the resistance of the conducting state and the insulating state for a fabric or for an individual nanotube in that fabric can vary by a factor of 10, 10², or even 10⁶ or more. Suitable chemical functionalization, derivitization, and/or modification can be made to a nanotube or nanotube fabric in order to adjust the initial resistance values appropriately, in addition to the simple control of fabric porosity.

A fabric of nanotubes, deposited on a suitable substrate, can also be patterned, and the electrical conductivity of defined portions of the fabric can be controllably modified in accordance with the pattern to result in a nanotube fabric having some portions with a higher conductivity than others. In one aspect, patterned regions of insulating nanotube fabric, which can be used as interlayer dielectrics, can be fabricated simultaneously with patterned regions of electrically conducting nanotube fabric, which can be used as electrical traces.

These patterned nanotube fabrics can be used as part of hybrid circuits involving CMOS technology and electronics. Other applications for such fabrics include but are not limited to commercial products that can employ an insulating carbon nanotube (CNT) fabric, such as a dielectric layer between conducting interconnect lines. Other products that can be envisioned are the simultaneous formation of conducting and insulating layers for interconnect technology. This may reduce the difficulty and cost of fabricating multiple layered interconnect lines as done currently, e.g., with copper (or any other metal or conductor) and interlayer dielectric.

Nanotubes can be applied to a surface of a substrate by any appropriate means including by spin coating, dipping, aerosol application, or they can be grown by use of catalysts, etc. Ribbons, belts or traces made from a matted layer of nanotubes or a non-woven fabric of nanotubes can be used as electrically conductive elements. At points in this disclosure, the patterned fabrics are referred to as traces or electrically conductive articles. In some instances, the ribbons are suspended, and in other instances they are disposed on a substrate. In some instances, they are used to deflect to certain states under electrical control, and in other instances they do not move and instead are used simply to carry an electrical current or voltage, as well as providing excellent thermal conductivity. Numerous other applications for patterned nanotubes and patterned nanotube fabrics include, but are not limited to sensor applications, photonic uses, etc. The new nanotube belt structures are believed to be easier to build at the desired levels of integration and scale (of number of devices made) and the geometries are more easily controlled. The new nanotube ribbons are believed to be able to more easily carry high current densities without suffering the problems commonly experienced or expected with metal traces.

Under certain embodiments, electrically conductive articles may be made from a patterned nanotube fabric, layer, or film; using individual nanotubes is problematic because of difficulties in growing or depositing them with suitably controlled orientation, length, and the like. Creating traces from nanotube fabrics allows the traces to retain many if not all of the benefits of individual nanotubes. Moreover, traces made from nanotube fabric have benefits not found in individual nanotubes. For example, since the traces are composed of many nanotubes in aggregation, the trace will not fail as the result of a failure or break of an individual nanotube. Instead, there are many alternate paths through which electrons may travel within a given trace. In effect, a trace made from nanotube fabric creates its own electrical network of individual nanotubes within the defined trace, each of which may conduct electrons. Moreover, by using nanotube fabrics, layers, or films, current technology may be used to create such traces. The nanotube matte or non-woven fabric is grown or deposited on a surface, such as that of a silicon wafer, to form a contiguous film of a given density. The two dimensional film can then be patterned to generate electrically conductive lines or traces ranging in width from 1 nm (or the intrinsic minimum size of a given nanotube) to hundreds of microns or greater, depending on the application and context. The pattern can be generated at multiple length and width scales to allow the interconnection of various sized semiconductor devices such as transistors or memory elements and eventually fanning out to bond pads or other interconnecting materials or constructs. The nanotube interconnects can be metallized if necessary to connect different materials because of their intrinsic properties that allow easy contact to metallic or semiconductor materials. Nanotubes may be filled with metal or other material and thereby create nanowires encapsulated within nanotube lumens, see e.g., Govindaraj, A., et al., “Metal Nanowires and Intercalated Metal Layers in Single-Walled Carbon Nanotube Bundles,” Chem. Mater. 2000, 12, 202-205, the entire contents of which are hereby incorporated herein by reference.

The ability to controllably adjust the conductivity of a nanotube fabric allows for the creation of an insulating carbon nanotube fabric, having dielectric characteristics, which can be employed as a dielectric layer in integrated circuit (IC) technology. As illustrated below, converting a conducting nanotube fabric into an insulating fabric opens the possibility of depositing and patterning a conducting and insulating fabric simultaneously in one step for utilization in integrated circuit (IC) technology. It is important to note that the conducting and insulating layers can be deposited simultaneously with a single CNT application. Utilizing conventional photolithography and RIE technology the conducting nanotube fabric can readily be converted into an insulating fabric. This could be a major advance in current multi-layered interconnect technology, which currently requires multiple metal deposition and dielectric deposition steps.

The traces and electrically conductive articles may be used in other forms of circuits. For example, nanotube traces may be used for their ability to withstand high current densities, normally found in very small sized traces (e.g., sub 10 nm regimes). They may also be used to reduce the likelihood of contaminating other circuit features, depending on the type of nanotube and substrate used in a given application.

While these interconnects can primarily be formed of a monolayer of nanotubes, multilayer ribbons and mattes can also be envisioned using proper growth/application conditions. This requires control of parameters including, but not limited to catalyst composition and concentration, functionalization of the underlying surface, spin coating parameters (length and RPM, for example 10-40 seconds, 50-5000 rpm), growth time, temperature and gas concentrations and spin coating solution concentration and number of applications.

Unlike the prior art which relies on directed growth or chemical self-assembly of individual nanotubes, preferred embodiments utilize fabrication techniques involving thin films and lithography. This method of fabrication lends itself to generation over large surfaces especially wafers of eight inches or even twelve inches or more. The ribbons should exhibit improved performance over individual nanotubes, by providing redundancy of conduction pathways contained within the ribbons. In other words, if an individual nanotube breaks, other nanotubes within the ribbon provide conductive paths.

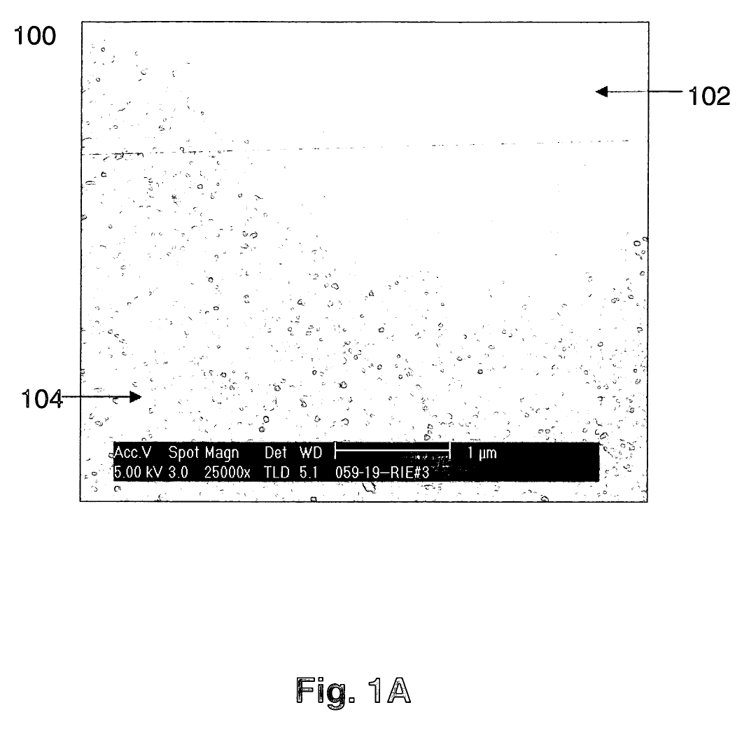

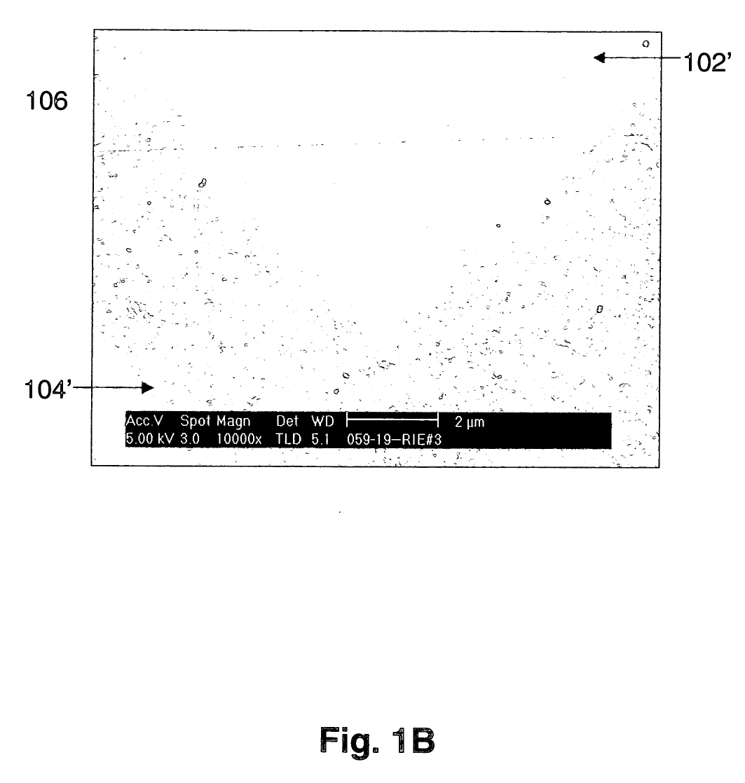

Patterning and processing a nanotube fabric, layer, or film can fabricate electrically conductive nanotube articles, such as traces, embedded in an insulating nanotube matrix. FIGS. 1A and 1B show FESEM images of carbon nanotube fabrics that were initially entirely electrically conducting, and which now have selected portions that are electrically insulating. FIGS. 1A and 1B show structures 100 and 106, respectively, which have respective regions 102, 102′ of conducting non-woven nanotube fabric, and regions 104, 104′ of insulating non-woven nanotube fabric. Regions 104, 104′ were converted from conductive to insulating nanotube fabric using a plasma process, described in greater detail below, but any appropriate process can be used. It should be noted that nanotubes in the insulating regions 104, 104′ appear to be broadened compared to those in the conducting regions 102, 102′.

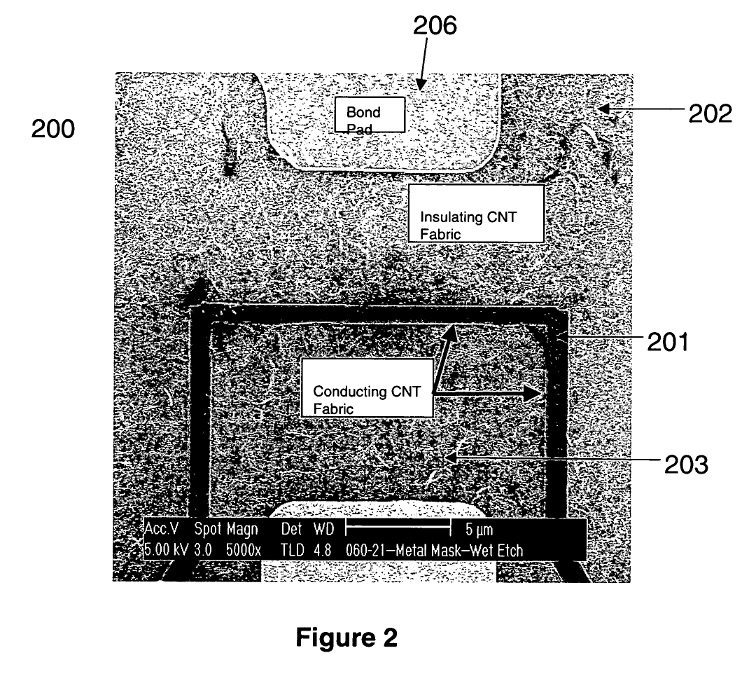

FIG. 2 is an FESEM image of a more complicated patterned nanotube structure 200. Structure 200 includes a region 201 of conducting nanotube fabric, which functions as an electrical trace or interconnect. Structure 200 also includes regions 202 and 203 of insulating nanotube fabric, which isolate conducting region 201. As in FIGS. 1A and 1B, the insulating regions 202, 203 of the fabric appears broadened compared to those in conducting region 201. Structure 200 was fabricated by depositing a conductive nanotube fabric over a substrate, protecting region 201 using standard photolithographic techniques, and then modifying the electrical conductivity of regions 202, 203 to form an insulating fabric. In effect, the electrical trace of region 201 was fabricated simultaneously with insulating regions 202 and 203. Additional features can be added to structure 202, such as bond pad 206. Note that insulating region 202 electrically insulates conductive region 201 from bond pad 206. Other device components, including other nanotube structures, can be included over or under structure 200 to provide other functionality.

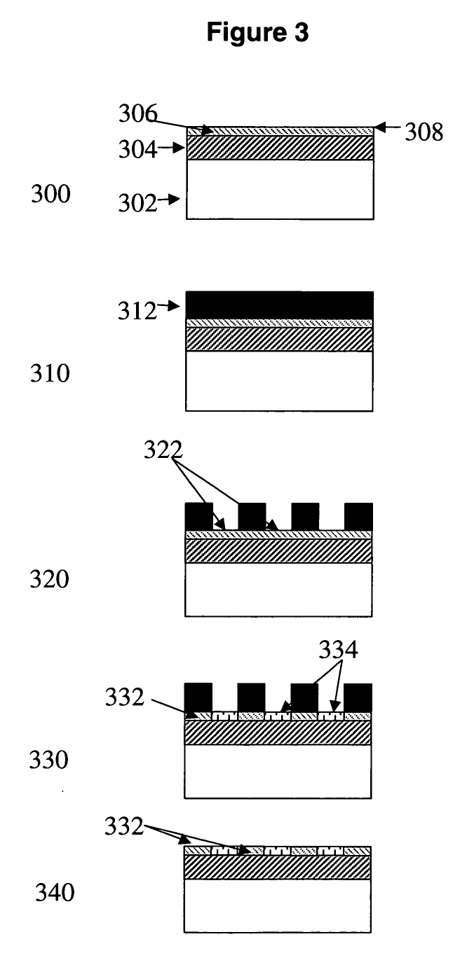

FIG. 3 illustrates steps in a method of patterning a non-woven fabric initially made from conducting and/or semiconducting nanotubes. The nanotubes can be applied by any appropriate means and the electrical characteristics of the nanotubes may be controlled by adjusting the composition and density of the fabric. One method of depositing a nanofabric of nanotubes is by deposition and spin coating. If the film is deposited, pre-grown nanotubes may be used. For example, under certain embodiments, nanotubes may be suspended in a solvent in a soluble or insoluble form and spin-coated over a surface to generate a nanotube film. In such an arrangement the film created may be one or more nanotubes thick, depending on the spin profile and other process parameters. Appropriate solvents include and are not limited to: dimethylformamide, n-methylpyrollidinone, n-methyl formamide, orthodichlorobenzene, paradichlorobenzene, 1,2, dichloroethane, ethyl lactate, alcohols, water with appropriate surfactants such as sodium dodecylsulfate or TRITON X-100, water alone, anisol or other solvents. The nanotube concentration and deposition parameters such as surface functionalization, spin-coating speed, temperature, pH and time can be adjusted for controlled deposition of monolayers or multilayers of nanotubes as required. The nanotube film could also be deposited by dipping the wafer or substrate in a solution of soluble or suspended nanotubes. The film could also be formed by spraying the nanotube in the form of an aerosol onto a surface. When conditions of catalyst composition and density, growth environment, and time are properly controlled, nanotubes can be made to evenly distribute over a given field that is primarily a monolayer of nanotubes. In the event that nanotubes are deposited on a surface at room temperature by spin-coating of a solution or suspension of nanotubes then the choice of substrate materials is expanded substantially. In this case there is no high temperature step and any material typically compatible with the device using nanotube fabrics would be acceptable. Other methods of providing and patterning non-woven nanotube fabrics are described in greater detail below.

As shown in FIG. 3, a first structure 300 is created or supplied: structure 300 having a substrate 302. The material of substrate 302 can be selected from any material that can stand up to subsequent patterning steps and provide sufficient support to the patterned nanotube fabric. Substrate material can include, but is not limited to, silicon, silicon oxide, silicon nitride, any material suitable for use with semiconductor or electronic applications, or any material appropriate for use in the field in which the patterned fabric will be used. Structure 300 also includes optional support layer 304, which may be an insulator, and its presence and composition depend on the final use of the patterned fabric.

Nanotube fabric layer 306 is applied over layer 304 by any appropriate means, such as those described herein and in the incorporated patent references. Topmost surface 308 of nanotube fabric layer 306 is illustrated. A resist layer 312 is applied to surface 308, e.g., by spin coating, thus forming intermediate structure 310. The resist 312 is patterned by exposure or the like to define conductive traces, leaving portions of exposed nanotube fabric 322, thus forming intermediate structure 320. Other pattern mask processes can also be employed such as hard masking, shadow masking, metal lift-off masks, etc.

The nanotube fabric layer 306 is then exposed to reactive ions, e.g., using Reactive Ion Etch plasma, etc. in order to modify the electrical properties of the exposed regions 322 of nanotube fabric, e.g., to convert regions 322 from electrically conducting to insulating. The mask pattern protects the underlying CNT fabric from the plasma, preventing modification of the electrical conductivity of those masked portions. Unprotected portions 322 of the CNT fabric are fully converted to an insulating fabric 334, thus forming intermediate structure 330. Individual nanotubes in CNT fabric may have one or more portions or segments that overlap with the masked region, and one or more portions or segments that are not masked and therefore exposed to the reactive ion process. In this case, after ion reaction, some nanotubes of the CNT fabric will have both modified, e.g., insulating, and conducting portions or segments.

As a non-limiting example of an reactive ion process, a layer of nanotube fabric is deposited, e.g., spray coated, onto the surface of a silicon dioxide substrate, obtaining a sheet resistance of ˜300 Ohms-per-square. A photoresist layer (e.g., g-line, i-line, deep-UV, electron-beam, etc) is then coated over the nanotube fabric, and lithographically exposed and subsequently developed using standard photoresist integration techniques. A hard mask layer such as, but not limited to, 100 nm of Ge may also be used instead of photoresist. The lithographically defined mask covers some regions of the nanotube fabric, and exposes other regions. The wafer is then exposed to reactive ions that are suitable to modify the electrical conductivity of the exposed nanotube fabric, for example, a CF₄ plasma in a reactive ion etch machine, at 15 mTorr and 60 W, for 90 seconds. The areas not protected by photoresist are then converted from conducting nanotubes to insulating nanotubes. The length of time for the plasma exposure is dependent on the type of gas chemistry employed, the chamber pressure, the temperature at which the substrate is held, the power and the sheet resistance of the nanotubes, which is also dependent on the thickness of the nanotube fabric and the type of nanotubes used for the fabric. In some embodiments, partially reacting the nanotube fabric with the reactive ions is sufficient to increase the resistance of the fabric to the desired value. Lengthy reaction times may completely remove the carbon nanotubes from the exposed areas of the fabric. Other gases can be used besides CF₄, such as CHF₃, H₂, CH₄, SF₆, Ar, BCl₃, Cl₂, CCl₂F₂, SiCl₄, C₄F₈, HBr, and mixtures thereof, or any other gases or mixtures of gases that can provide a source of reactive (e.g., halogen) ions under appropriate conditions that interact with and modify the electrical conductivity of carbon nanotubes.

In general, nanotube fabrics that can usefully be modified have a porosity that exposes the majority of the nanotubes in the fabric to the reactive ions. This allows substantially all of the nanotubes in the fabric to be reacted to a desired degree, which enhances control over the final resistance of the fabric. In contrast, if a nanotube fabric is very thick, the reactive ions may not be able to reach and therefore not react with many nanotubes in the fabric. In this case, the maximum resistance of the fabric is limited by how many nanotubes are unreacted, i.e., are in their initial conducting state. Selecting the porosity of the nanotube fabric to allow facile adjustment of the resistivity of each individual nanotube in the fabric enhances the range through which the total (bulk) resistance of the fabric can be adjusted.

After reactive ion exposure, the patterned mask is removed, leaving structure 340, which includes a patterned region of conducting CNT fabric 332 including conducting and/or semiconducting nanotubes, and an insulating CNT fabric 334 including insulating nanotubes. The final resistance of insulating fabric 314 can be adjusted by adjusting various parameters of the reactive ion process.

In some cases, depending on the conversion parameters, the electrically insulating nanotubes can be made conducting again by an annealing process. A non-limiting case involves the annealing of the substrate that contains the insulating nanotubes in a vacuum of <50 mTorr at 400° C. for 30 minutes. For this case the fluorine ions that have attached to the surface, making the nanotubes insulating, desorb or are otherwise driven off of the nanotubes, returning the electrical properties of the nanotubes back to a conducting state. Depending on the amount of plasma damage on the nanotubes, it should be possible to obtain a complete reversal from insulating to the original conducting properties of the nanotubes. To facilitate the reversal of the nanotube conductivity, other annealing process such as forming gas anneals, rapid thermal anneals, etc. can also be employed.

FIG. 3 demonstrates an embodiment of a possible, but not limiting, process flow for the creation of a patterned conducting and insulating CNT fabric. Subsequent metallization may be used to form addressing electrodes or a fanned interconnect structure. The defined traces can have a width of at least 1 nm and as much as 100 microns or more depending upon the type of device or application in which the trace is to be used.

Intermediate structure 300 may be provided already including electronic interconnects or other functional elements as desired. Also, structure 340 may be further processed to include subsequently-created interconnects, metallizations and/or functional electronic and conductive elements.

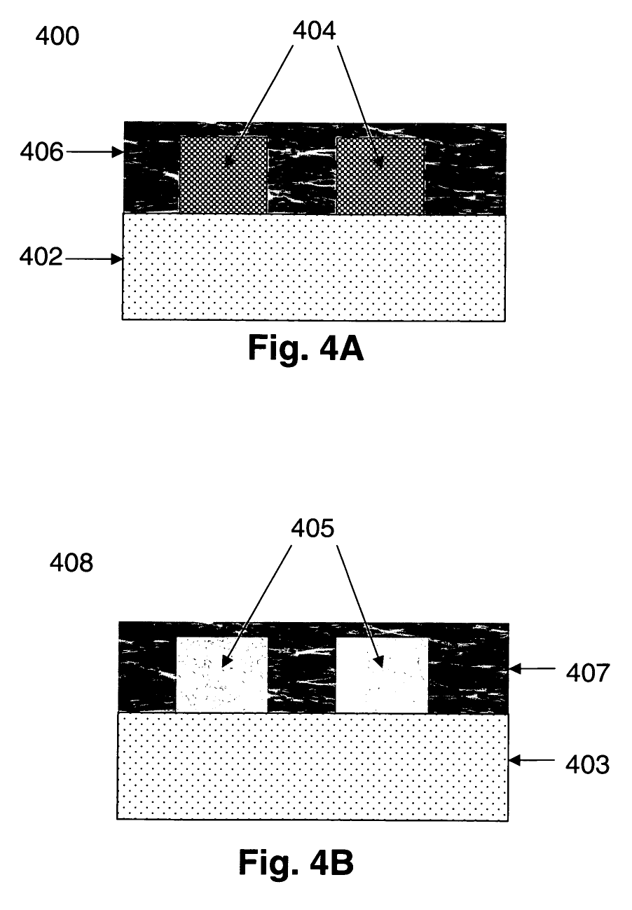

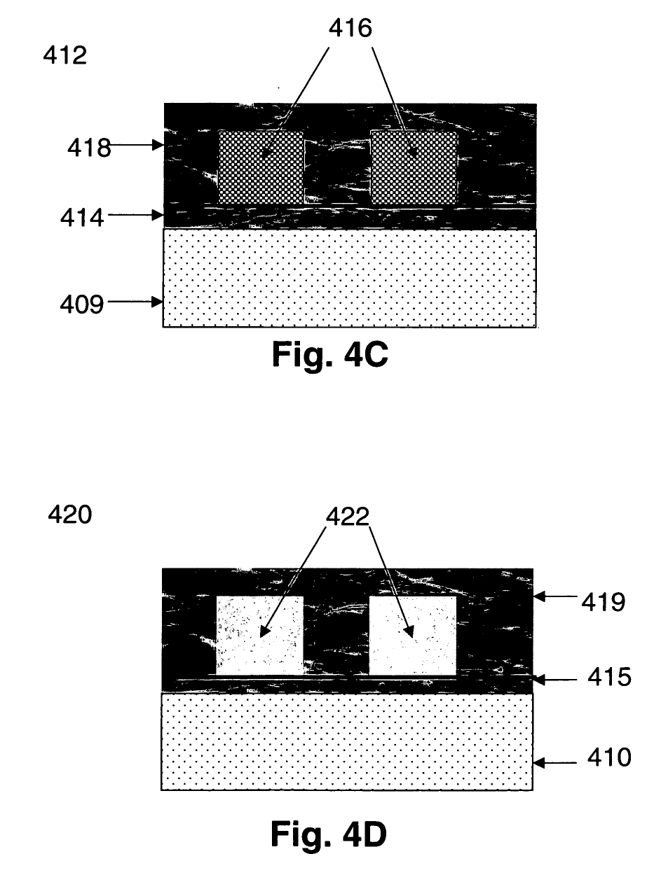

Insulating nanotube fabrics can also be used as a dielectric spacer between conductors, such as conducting metal lines. FIGS. 4A-4D illustrate four example structures that include insulating nanotube fabrics.

FIG. 4A illustrates structure 400 having a substrate 402, conducting plates 404, and dielectric/insulating nanotube fabric 406. Structure 400 is constructed by depositing conducting plates 404 onto substrate 402. Substrate 402 can be made of any appropriate material including, but not limited to, silicon dioxide, silicon, silicon nitride, etc. Conducting plates can be made of any suitable conductor, e.g., Ru, Ti, Cr, Al, Au, Pd, Ni, W, Cu, Mo, Ag, In, Ir, Pb, Sn, as well as metal alloys such as TiAu, TiCu, TiPd, PbIn, and TiW, or conductive nitrides, oxides, or silicides such as RuN, RuO, TiN, TaN, CoSiₓ and TiSiₓ. Conducting plates 404 can be fabricated by any appropriate means, such as by a physical, chemical, or electrochemical deposition process. Dielectric/insulating nanotube fabric 406 is then created in-between and on top of the conducting plates 404. Fabric 406 can be created by spin-coating, dipping, aerosol application, growth, or any appropriate method, and then adjusting its electrical resistivity/dielectric constant to a value that is appropriate for electrically isolating conducting plates 404 from each other. Some methods of creating nanotube fabrics are more fully described in the incorporated patent references.

FIG. 4B illustrates a structure 408 having a substrate 403, regions of conducting nanotube fabric 405, and dielectric/insulating nanotube fabric 407, fabricated as described herein. The regions of conducting nanotube fabric 405 provide electrically conductive traces within and along structure 408. Regions 405 may be fabricated using methods described in U.S. patent application Ser. No. 10/936,119, entitled “Patterned Nanoscopic Articles and Methods of Making Same,” filed Sep. 8, 2004, the entire contents of which are hereby incorporated by reference. In general, the electrical conductivity of regions 405 is not modified, so that their electrical resistance is very low. However, in some cases it may be desirable to adjust their electrical conductivity, e.g., using the methods described herein.

FIGS. 4C and 4D involve the complete encapsulation of the conducting plates.

FIG. 4C illustrates structure 412 having a substrate 409, a first layer of insulating nanotube fabric 414, conducting plates 416, and a second layer of insulating nanotube fabric 418. The creation of structure 412 includes depositing a layer of nanotube fabric onto the substrate, and adjusting its electrical conductivity, e.g., as described herein, to form an insulating layer 414. Next, conducting plates 416 are provided, substantially as described above. Then, conducting plates 416 are encapsulated with a second dielectric/insulating layer of nanotubes 418. Insulating nanotube layers 414 and 418 substantially insulate conducting plates from the substrate and from each other.

FIG. 4D illustrates a structure having a substrate 410, a first layer of insulating nanotube fabric 415, regions of conducting nanotube fabric 422, and a second layer of insulating nanotube fabric 418, which may be made substantially as described above and in the incorporated patent references.

The use of dielectric fabric makes possible the construction of multi-level interconnect schemes similar to those currently employed in the semiconductor industry. Another advantage of the use of insulating nanotube-based fabrics is that, due to the nature of the CNT material, any undesirable interaction between the metal lines and the insulating CNTs are minimized. Other materials used as insulators could deteriorate the electrical characteristics of the interconnect levels.

A possible application for this dielectric spacer is as an interlayer dielectric (ILD) material for metallization lines in integrated circuits. For these ILD materials, a low dielectric constant (κ=ε/εₒ where ε=permittivity of the material and εₒ=permittivity of a vacuum) is required to reduce the capacitance coupling between the metal lines. Silicon dioxide, highly employed ILD for metallization levels, has a κ˜3.9, while future dielectric materials will steadily approach 1 (κ for air or vacuum). The dielectric CNT fabric should be an ideal choice for an ILD barrier between 2 metal lines since the fabric contains a high porosity, meaning that the dielectric constant will be closer to the value of 1. This effect is similar to Aerogels (K ranging from 1.8-2.1, depending on porosity with higher porosities giving lower dielectric constants) which are a porous form of silicon dioxide. A rough linear extrapolation, where the effective dielectric constant (κ_{eff})=κ_{ILDCNT}−(κ_{ILDCNT}−κₐᵢᵣ)×Porosity, can be made by using the dielectric constant of diamond (˜5.5). See X. Xiao, et al., “Simulation of the dielectric constant of aerogels and estimation their water content,” Microelectronic Engineering, 55, 53-57, 2001, the entire contents of which are hereby incorporated by reference herein.

Since the insulating CNT fabric is highly porous (>80%), it can be expected that the dielectric constant of the insulating fabric is <2 with values approaching 1.5 at 90% porosity, reasonable porosity values for converted CNT fabrics. Other non-linear calculations will present lower dielectric constant values at lower porosities compared to the linear extrapolation.

The capacitance of two metal lines that are 3 μm wide by 100 μm long separated by an ILD CNT fabric 100 nm wide can easily be solved by using the equation C=κεₒA/L, giving a capacitance of ˜10⁻¹⁴ F, which is an order of a magnitude lower than if silicon dioxide had been employed (C˜10⁻¹³ F).

The pore size of the CNT ILD will also not alter when the wafer is annealed or raised to higher temperatures, which is an issue with other porous ILD materials such as Aerogels. CNT ILDs also have many advantages over other low-κ dielectrics in that they are easy to apply to a substrate without any toxic or harsh chemicals, do not require an anneal process, can withstand high temperatures, do not negatively interact with the substrate and can be fabricated simultaneously with conducting metal lines when employing the conducting CNT fabric as the metal interconnects as described above.

Patterned nanotube fabrics having controllable electrical characteristics, and density, can thus be provided on a substrate. When conditions of catalyst composition and density, growth environment, and time are properly controlled, nanotubes and nanotubes can be made to evenly distribute over a given field that is primarily a monolayer of nanotubes and nanotubes. Proper growth requires control of parameters including but not limited to catalyst composition and concentration, functionalization of the underlying surface, spin coating parameters (length, nanotube/nanotube suspension concentration and RPM), growth time, temperature and gas concentrations. The electrical properties of the resulting fabrics can then be modified as described herein.

While electrical traces and/or interconnects can primarily be formed of a monolayer of nanotubes, multilayer ribbons and mattes can also be envisioned using proper growth/deposition conditions. This requires control of parameters including but not limited to catalyst composition and concentration, functionalization of the underlying surface, spin coating parameters (length and RPM, for example), growth time, temperature and gas concentrations.

Subsequent metallization may be used to form addressing electrodes; alternatively, the nanotube fabric may be created over a substrate with previously embedded addressing electrodes.

The above techniques, i.e., the various growth, spin-coating, patterning, and etching operations may be performed using conventional, lithographic patterning techniques. Currently, this may result in feature sizes (e.g., width of ribbon 101) of about 180 nm to as low as 22 nm, but the physical characteristics of the components are amenable to even smaller feature sizes if manufacturing capabilities permit.

Nanotube fabrics may be applied by such methods as spin-coated catalyst-based growth, gas-phase catalyst-assisted CVD and spin-coating, or direct deposition of nanotubes. In the case of the catalyst-based growth as has been described above the catalyst is distributed on the surface either by spin-coating, or dipping the substrate in the catalyst material followed by standard washing protocols. In each of these cases the nanotubes are then grown via any appropriate method.

Because the spin coating and growth process causes the underside of such nanotubes to be in contact with planar surface on which they are grown, they exhibit a “self-assembly” trait. In particular, individual nanotubes tend to adhere to the surface on which they are grown whenever energetically favorable, such that they form substantially as a “monolayer.” Some nanotubes may grow over another so the monolayer is not expected to be perfect. The individual nanotubes do not “weave” with one another but can adhere with one another as a consequence of van der Waals forces; such van der Waals forces are attractive. In other embodiments of the present invention, the van der Walls interactions between the nanotubes that comprise the nanofabric may be repulsive or neutral, depending upon the desired application. The nanotubes of the present invention may be functionalized to alter and or enhance the van der Walls interactions as well. In certain applications the nanotube fabric will be thicker than a monolayer and can be made much thicker even as high as 1 micron or greater for applications which require particular resistive properties.

Properties of the nanotube fabric can be controlled through deposition techniques. Once deposited, the nanofabrics can then be patterned and etched to generate nanotube traces. Nanotube fabrics can be generated through growth directly upon a substrate or through direct application to a substrate. In the case of application, the types of substrates which can be used are nearly limitless since the application procedure occurs at room temperature. This allows for such diverse substrates as plastics, glass or flexible materials to be used. The reactive ion process used to modify the electrical conductivity of nanotube fabrics can in some cases potentially damage the underlying substrate. In these cases, the reactive ion process conditions can be selected or modified to be compatible with the substrate. Additionally, the substrate can be protected, e.g., with protective layers.

Monolayer nanotube fabrics can be achieved through specific control of growth or application density. More nanotubes can be applied to a surface to generate thicker fabrics with less porosity. Such thick layers, up to a micron or greater, may be advantageous for applications which require lower resistance.

In certain embodiments, nanotubes are applied substantially unrestrained in the x- and y-axis directions, but are substantially restricted in the z-axis (perpendicular to the underlying substrate) as a consequence of the self-assembly trait. Other embodiments may supplement the above approach to growing nanotube layer 122 with the use of field-oriented or flow-oriented growth techniques. Such supplementation may be used to further tailor growth such that any growth in one planar axis (e.g., the -x-axis) is retarded. This allows for a more even coverage of the desired area with a planar interwoven monolayer coating of nanotubes with a controllable density.

Nanotube fabrics can be characterized in a variety of ways including through measurement of their electrical properties. Determination of the resistance of a nanotube fabric per square would be a typical characterization measurement. For thinner and more porous nanotube fabrics a typical resistance measurement would be 1-10 kΩ/□. For more dense nanotube fabrics the typical resistance could range from 20 milliΩ/□ to 1 kΩ/□ with a preferred embodiment having a density of around 10-50 Ω/□ for a typical thick nanotube fabric. An insulating fabric would have a sheet resistance value greater than 1 MΩ/□, for example, greater than 100 MΩ/□, 1 GΩ/□, or even greater than 1 TΩ/□.

Nanotube fabrics can be quite porous allowing material to be etched from below the fabric itself. In this instance the use of a sacrificial etchant layer would allow the nanotube fabric to be suspended between two supports. Such an orientation of a nanotube fabric could furthermore be firmly pinned to the supports by evaporation of an additional material onto the nanotube fabric. This material can include insulators, semiconductors or conductors, and can be evaporated through a porous nanotube fabric to prevent the nanofabric from dislodging from the supports. Such a pinning support layer may also be used for making electrical contact to the nanotube fabric especially for electrical stitching to lower the overall resistance of a nanotube trace. Non-limiting examples of materials that may be used in such a pinning embodiment include silicon dioxide, silicon nitride, silicon, aluminum, tungsten, titanium, copper, gold, silver, molybdenum and others.

Electrical traces and/or interconnects fabricated according to some embodiments can be addressed/connected using traces or electrically conductive articles made from other nanotube layers or traces made from patterned carbon nanotubes, or made of any appropriate material. The layers may have thickness of about 1 nm or less, i.e., the thickness of a given nanotube. A nanotube matte or non-woven fabric can be grown or deposited on a surface, such as that of a silicon wafer, to form a contiguous film of a given density. The two dimensional fabric can then be patterned to generate electrically conductive lines or traces ranging in width from 1 nm to hundreds of microns or greater, depending on the application and context. The pattern can be generated at multiple length and width scales to allow for appropriate desired end use, including but not limited to the interconnection of various sized semiconductor devices such as transistors or memory elements and eventually fanning out to bond pads or other interconnecting materials or constructs sensor applications, actuators, transistors, diodes, triodes and pentodes. The nanotube interconnects can be metallized if necessary to connect different materials because of their intrinsic properties that allow easy contact to metallic or semiconductor materials.

Furthermore the substrates that conducing and insulating nanotubes may be used with are not limited to rigid substrates. Nanofabrics may be used in conjunction with flexible substrates unlike those thin film conductors and insulators of the current technology.

### EXAMPLE 1

A layer of carbon nanotubes from several nanometers up to a micron thick is applied to a substrate either by spray coating, spin coating, dip coating, etc. The carbon nanotubes are then exposed to a gas that provides reactive ions, e.g., CF₄, CHF₃, H₂, CH₄, SF₆, Ar, BCl₃, Cl₂, CCl₂F₂, SiCl₄, C₄F₈, HBr, and mixtures thereof, as described in greater detail above, in a reactive ion etch chamber. The reactive ions react with the carbon nanotubes, modifying the nanotubes' electrical conductivity. The nanotube layer can be converted to a high resistance nanotube layer, or it can be converted to an intermediate resistance nanotube layer. Selection of plasma power in the RIE chamber, reactive ion density and reaction time, can minimize morphological damage of the CNT fabric while modifying the electrical properties as desired. As an example, a carbon nanotube fabric is sprayed onto a substrate to produce a low Ohm resistance fabric (<50Ω per square). After depositing the CNT fabric, the substrate is loaded into an RIE chamber where CF₄ gas is introduced at a pressure of 15 mTorr. The CNT fabric is then exposed to a plasma at 60 W for 2 minutes. This process time sufficiently converts the thick, conducting nanotube fabric (>50 nm) into a substantially insulating fabric (open sheet resistance). Processing conditions are not limited to these parameters.

### EXAMPLE 2

The steps of Example 1 are repeated, and then, a mask pattern is fabricated on top of the CNT fabric by spinning, exposing and developing photoresist. The substrate containing the CNT fabric was exposed to RIE plasma (containing CF₄ gas at 30 mTorr at 30 Watts for 30 seconds). Unprotected portions of the CNT fabric were fully converted to an insulating fabric, while the mask prevented the underlying portion from being converted to a non-conducting CNT fabric. After RIE plasma exposure, the patterned mask was removed, leaving a defined region of patterned conducting CNT fabric within an insulating CNT fabric.

### Other Embodiments

An alternate embodiment involves the creation of dielectric features of carbon nanotubes (CNTs) and nanotubes from a fabric initially including conducting nanotubes, or a mixture of conducting and semiconducting nanotubes.

In another embodiment, pinning of nanotubes onto the supports using an overlaid thin coating is done to prevent slipping of tubes during operation. The porous nature of nanotube fabrics allows materials to be evaporated over and through the fabric. Materials can also be etched below the fabric.

The electrical properties of the layers and electrically conductive articles can be tuned by controlling the cross section of the nanotube ribbons. For example, the ribbon thickness may be increased at a given width and nanotube density. The higher the cross section, the greater the number of conduction channels leading to enhanced electrical properties.

The method of preparing the nanotube ribbons allows continuous conductivity even over rough surface topologies. In contrast, typical evaporation of metallic electrodes would suffer from structural and thus, electrical defects.

Methods to increase the adhesion energies through the use of ionic, covalent or other forces can be envisioned to alter the interactions with the electrode surfaces. These methods can be used to extend the range of bistability with these junctions.

In yet a further embodiment, the property of nanotube adhesion to non-planar surfaces is exploited. Depending on the composition and thickness of the nanotubes used, the fabric made by spin coating or other application may substantially conform to a non-planar surface. For example, a fabric made from silicon nanotubes, 5 nm in diameter, will conform to the peaks and valleys of a non-planar surface, while a fabric made using silicon nanotubes greater than 20 nm in diameter, which remain more rigid than 5 nm nanotubes, will not conform as well. The fabric may also substantially conform to a vertical feature of a substrate. Vertical nanotube fabrics are described in greater detail in U.S. Pat. No. 6,924,538, entitled “Devices having vertically-disposed nanofabric articles and methods of making the same,” the entire contents of which are hereby incorporated herein by reference. The fabric also need not necessarily substantially conform to any surface. For example, the fabric can be partially suspended, e.g., over a trench. Architectures for suspended nanotubes are described in greater detail in the incorporated patent references.

In another embodiment, a solution of carbon nanotubes (CNTs) is spray-coated onto a substrate to produce a non-woven fabric that can patterned for use as interconnect lines for integrated circuits. The CNT fabric can range from a single monolayer to several monolayers thick. The spray coated solution includes carbon nanotubes (SWNTs or MWNTs) solvated in a solvent (e.g., o-dichlorobenzene, di-methylformamide, ethyl lactate, DI water, etc.).

To apply the CNTs by spray-coating, a solution (as described above) is filled into an appropriate spray gun that enables the application of the solution onto a substrate. The substrate is placed on a hot plate to allow for quick evaporation of excess solvent, preventing liquid accumulation on the wafer. If the solvent is allowed to accumulate on the substrate, dense regions of clumped CNTs may form, creating fabric uniformity issues. Because the solvent evaporates, the hot plate may not be needed for all solvents (i.e. low vapor pressure solvents). To enhance the uniformity of the spray-coating method, the CNT solution can also be applied in conjunction with the spin-coating method. Spray coating the CNT solution provides enhanced control over the location of CNT deposition, potentially eliminating the need for an edge bead removal (EBR) process.

Resistance values of an as-sprayed blanket nanotube fabric can range from, e.g., ˜1 Ω/sq to 1 kΩ/sq or greater. This allows fabrication of a thick, uniform fabric with sheet resistances of less than 50 Ω/sq. A forming gas or vacuum anneal can also be performed to further lower the sheet resistance of the fabric.

To create low resistance CNT interconnects, the CNT solution is spray-coated and the fabric is patterned on a desired substrate, e.g., with the RIE-based methods of electrical conductivity conversion described herein. These patterned low resistance (<50 Ω/sq) fabrics can now be employed for local level and global level interconnects. Importantly, it is expected that the capacitive line-to-line coupling of closely spaced CNT interconnect lines is substantially reduced (>90%), compared to typical metal interconnects (e.g. Cu), due to high porosity of the CNT fabric.

The electrical conductivity of these fabrics can also be modified, e.g., using the techniques described herein, to provide patterned insulators.

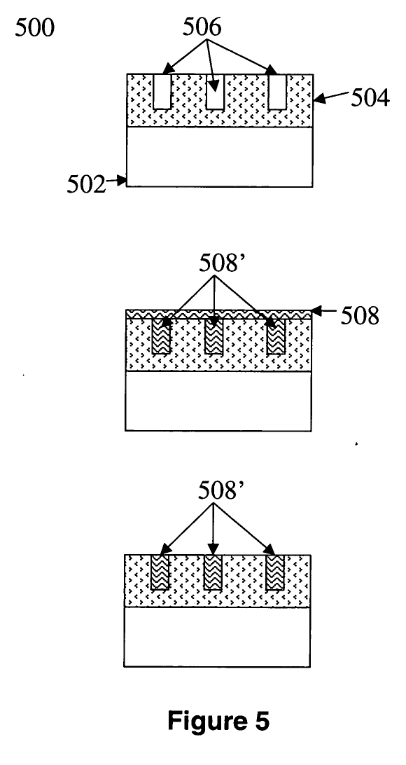

Thick (>5 nm) nanotube fabrics, having a low sheet resistance between 1Ω to <1 kΩ, can also be patterned. Unlike monolayer CNT fabrics, oxygen plasma etching of a several monolayer thick fabric is difficult. To effectively pattern the thick nanotube fabric, a process is employed according to certain embodiments, as illustrated in FIG. 5, showing process 500. This process involves creating trenches/vias 506 into a dielectric layer 504, which is supported by substrate 502. The trenches 506 typically have dimensions of 100-500 nm deep and 200-1000 nm wide; however, the trenches are not constrained to these dimensions for the patterning of the nanotube fabric. After the trench/via construction, a thick nanotube fabric 508 is deposited by spray-coating (spin-coating, dip-coating, etc. may also be employed). Thick nanotube fabric also fills the trenches creating nanotube layer 508′. Once the CNTs are deposited on the substrate and adequately fill the trench/via, the CNT fabric that is not contained within the trench is polished off the substrate. Polishing of the CNT fabric can be performed with a standard polishing cloth (e.g. Rayon Fine) that has been wetted with isopropyl alcohol (IPA). Other solvents may be employed such as DI water, acetone, etc. The solvent is not a critical or limiting step. The polishing of the nanotube fabric removes all of the nanotubes that are not contained within the trench, leaving nanotubes 508′ inside the trench 506.

The electrical conductivity of nanotubes 508′ can subsequently be modified, e.g., using the methods described herein, to provide regions of nanotube fabric having a specified electrical conductivity. For example, nanotubes 508′ can be converted to substantially insulating nanotubes. In some embodiments, structure 504, 508′ forms an insulator bilayer, and the presence of insulating nanotubes 508′ would lower the effective dielectric constant of the bilayer. In other embodiments, layer 504 can be provided as a conductor, in which case nanotubes 508′ having a high resistance would form insulating lines through the conductor.

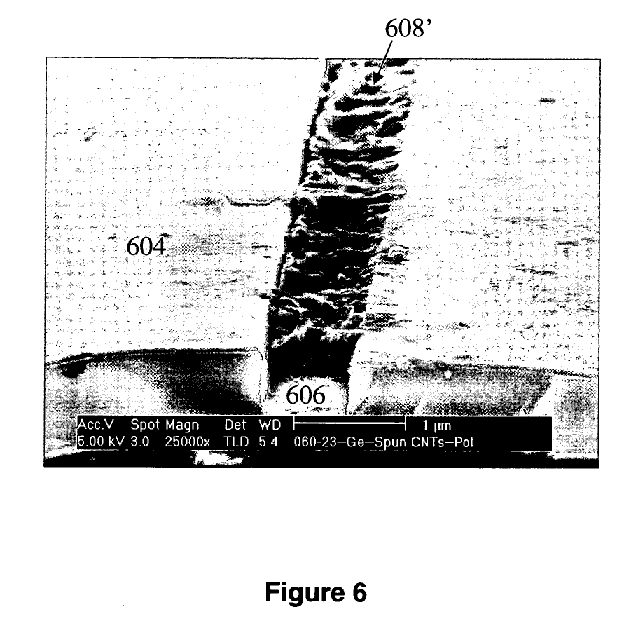

FIG. 6 shows an SEM image of nanotube fabric 608′ that has been produced using the process described regarding FIG. 5.

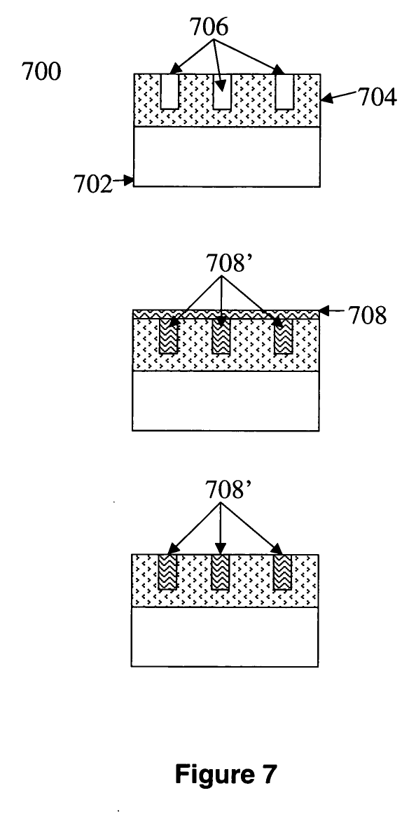

A nanotube fabric can also be patterned with a spray removal process, according to certain embodiments, as shown in FIG. 7 (structure 700). Constructing similar trenches 706 as for the method illustrated in FIG. 5, carbon nanotubes 708 and 708′ are deposited on the insulator 704 and inside trenches 706. Once the desired resistance (thickness) of the fabric is obtained, a solvent (e.g., IPA, DI, etc.) is sprayed over the substrate to selectively remove the portions of the nanotube fabric that were not deposited within the trench, leaving only nanotubes 708′. As for the example shown in FIG. 5, the electrical conductivity of nanotubes 708′ can be modified, e.g., using the methods described herein, to provide regions of nanotube fabric having a specified electrical conductivity.

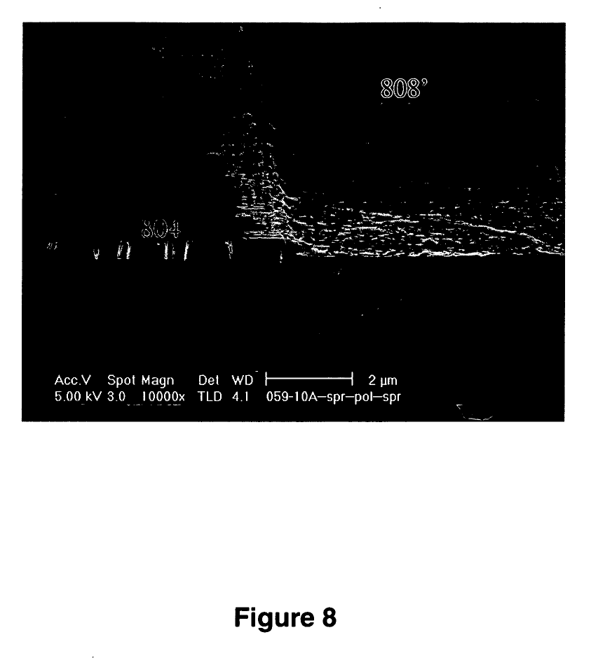

FIG. 8 shows an SEM image of nanotube fabric 808′ that has been produced using the process described regarding FIG. 7.

This application is related to the following references, which are assigned to the assignee of this application and are hereby incorporated by reference herein in their entireties:

Electromechanical Memory Array Using Nanotube Ribbons and Method for Making Same (U.S. Pat. No. 6,919,592);

Electromechanical Memory Having Cell Selection Circuitry Constructed With NT Technology (U.S. Pat. No. 6,643,165);

Hybrid Circuit Having NT Electromechanical Memory (U.S. Pat. No. 6,574,130);

Electromechanical Three-Trace Junction Devices (U.S. Pat. No. 6,911,682);

Methods of Making Electromechanical Three-Trace Junction Devices (U.S. Pat. No. 6,784,028);

Nanotube Films and Articles (U.S. Pat. No. 6,706,402);

Methods of NT Films and Articles (U.S. Pat. No. 6,835,591);

Methods of Making Carbon Nanotube Films, Layers, Fabrics, Ribbons, Elements and Articles (U.S. patent application Ser. No. 10/341,005), filed on Jan. 13, 2003;

Methods of Using Thin Metal Layers to Make Carbon Nanotube Films, Layers, Fabrics, Ribbons, Elements and Articles (U.S. patent application Ser. No. 10/341,055), filed Jan. 13, 2003;

Methods of Using Pre-formed Nanotubes to Make Carbon Nanotube Films, Layers, Fabrics, Ribbons, Elements and Articles (U.S. patent application Ser. No. 10/341,054), filed Jan. 13, 2003;

Carbon Nanotube Films, Layers, Fabrics, Ribbons, Elements and Articles (U.S. patent application Ser. No. 10/341,130), filed Jan. 13, 2003;

Non-volatile Electromechanical Field Effect Devices and Circuits using Same and Methods of Forming Same (U.S. patent application Ser. No. 10/864,186, Publication No. 2005/0062035), filed Jun. 9, 2004;

Electro-Mechanical Switches and Memory Cells Using Horizontally-Disposed Nanofabric Articles and Methods of Making the Same, (U.S. patent application Ser. No. 10/776,059, Publication No. 2004/0181630), filed Feb. 11, 2004; and

Electro-Mechanical Switches and Memory Cells using Vertically-Disposed Nanofabric Articles and Methods of Making the Same (U.S. Pat. No. 6,924,538).

It will be further appreciated that the scope of the present invention is not limited to the above-described embodiments but rather is defined by the appended claims, and that these claims will encompass modifications of and improvements to what has been described.

What is claimed is:

1. A method of modifying the electrical resistance of individual nanostructures within a layer of said nanostructures, the method comprising:
providing a layer of nanostructures, said layer characterized by an electrical resistance; and
exposing the layer of nanostructures to a type and amount of reactive ions sufficient to increase the electrical resistance of the layer of nanostructures by a desired amount,
wherein the layer of nanostructures has a sufficiently low porosity to substantially expose each individual nanostructure within the layer to the reactive ions.

2. The method of claim 1, wherein exposure to said reactive ions increases the electrical resistance of substantially each individual nanostructure within the layer.

3. The method of claim 1, wherein exposure to said reactive ions increases the electrical resistance of the layer of nanostructures by a factor of at least 10.

4. The method of claim 1, wherein the layer of nanostructures comprises a non-woven fabric of nanostructures.

5. The method of claim 1, wherein each individual nanostructure within the layer lies substantially parallel to a substrate.

6. The method of claim 1, wherein the nanostructures comprise single-walled carbon nanotubes.

7. The method of claim 1, wherein the nanostructures comprise multi-walled carbon nanotubes.

8. The method of claim 1, wherein the nanostructures comprise nanowires.

9. The method of claim 1, further comprising heating the layer of nanostructures to reduce the electrical resistance of the layer of nanostructures.

10. The method of claim 1, further comprising depositing a patterned mask over a defined portion of the layer of nanostructures before exposing the layer to reactive ions.

11. The method of claim 10, wherein the defined portion of the layer is not exposed to the reactive ions and its electrical resistance is not increased.

12. The method of claim 10, wherein the defined portion of the layer forms an electrically conductive trace.

13. The method of claim 1, wherein the reactive ions are provided by at least one of CF₄, CHF₃, H₂, CH₄, SF₆, Ar, BCl₃, Cl₂, CCl₂F₂, SiCl₄, C₄F₈, HBr, and mixtures thereof.

14. The method of claim 1, wherein providing the layer of nanostructures comprises growing the nanostructures on a substrate.

15. The method of claim 1, wherein providing the layer of nanostructures comprises depositing pre-grown nanostructures on a substrate.

16. A nanotube fabric of adjustable electrical resistance, comprising:
a non-woven fabric of nanotubes, the non-woven fabric characterized by an electrical resistance,
wherein substantially each individual nanotube in the fabric is electrically resistive;
wherein the electrical resistance of substantially each individual nanotube in the fabric is increasable in response to reaction with a type and amount of reactive ions sufficient to increase the electrical resistance of the fabric by a desired amount; and
wherein the electrical resistance of substantially each individual nanotube in the fabric is reducible in response to a period and temperature of heating sufficient to reduce the electrical resistance of the fabric by a desired amount.

17. The fabric of claim 16, wherein the non-woven fabric of nanotubes forms an electrical insulator.

18. The fabric of claim 16, wherein the electrical resistance of the fabric is a function of a number of functional groups attached to substantially each individual nanotube of the fabric.

19. The fabric of claim 16, wherein reaction of the fabric with reactive ions at least partially functionalizes substantially each individual nanotube of the fabric.

20. The fabric of claim 16, wherein heating of the fabric at least partially drives functional groups off of substantially each individual nanotube of the fabric.

21. The fabric of claim 16, wherein heating of the fabric reduces the electrical resistance of the fabric below about 10,000 Ω/square.

22. The fabric of claim 16, wherein the electrical resistance of the fabric is at least about 1 MΩ/square.

23. The fabric of claim 16, wherein the electrical resistance of the fabric is at least about 1 TΩ/square.

24. The fabric of claim 16, wherein substantially each individual nanotube of the fabric has an electrical resistance of about 1 MΩ.

25. The fabric of claim 16, wherein the reactive ions are provided by a gas in a plasma.

26. The fabric of claim 16, wherein the gas comprises at least one of CF₄, CHF₃, H₂, CH₄, SF₆, Ar, BCl₃, Cl₂, CCl₂F₂, SiCl₄, C₄F₈, HBr, and mixtures thereof.

27. A patterned nanotube fabric, comprising:
a non-woven fabric of nanotubes, the fabric having a first defined region comprising nanotubes that substantially each individually are in a resistive state, and a second defined region comprising nanotubes that substantially each individually are in a conductive state.

28. The fabric of claim 27, wherein the first defined region has an electrical resistance that is at least about 10 times greater than that of the second defined region.

29. The fabric of claim 27, wherein the first defined region has an electrical resistance that is at least about 10⁶ times greater than that of the second defined region.

30. The fabric of claim 27, further comprising at least one nanotube having a relatively high resistance segment that overlaps the first defined region, and a relatively low resistance segment that overlaps the second defined region.

31. The fabric of claim 27, wherein the first defined region forms an electrical insulator.

32. The fabric of claim 27, wherein the second defined region forms an electrically conductive trace.

33. The fabric of claim 33, wherein the first defined region electrically insulates the electrically conductive trace from at least one conductor.

34. The fabric of claim 27, wherein the nanotubes of the second region form an electrical network of nanotubes that define a plurality of conductive pathways within the second defined region.

35. The fabric of claim 27, wherein the first region and second region touch each other along at least one border.

36. The fabric of claim 27, wherein the first region and second region are substantially coplanar.

37. The fabric of claim 27, wherein the non-woven fabric of nanotubes comprises substantially a monolayer of nanotubes.

38. The fabric of claim 27, wherein the non-woven fabric of nanotubes is porous.

39. The fabric of claim 27, wherein the non-woven fabric of nanotubes comprises substantially single-walled nanotubes.

40. The fabric of claim 27, wherein a lithographically patterned strapping material contacts at least a portion of the second defined region.

41. The fabric of claim 27, wherein the substrate is flexible.

42. The fabric of claim 27, wherein the substrate comprises at least one of plastic, glass, silicon, silicon oxide, or silicon nitride.

43. A circuit, comprising:
a first conductive electrode;
a second conductive electrode in spaced relation to the first electrode; and
a non-woven nanotube fabric of nanotubes substantially to fill the volume between the first and second electrodes, wherein substantially each individual nanotube of the fabric is in an electrically resistive state.

44. The circuit of claim 43, wherein the fabric electrically insulates the first electrode from the second electrode.

45. The circuit of claim 43, wherein the fabric substantially encapsulates the first and second electrodes.

46. The circuit of claim 43, wherein the fabric forms an interlayer dielectric between the first and second electrodes.

47. The circuit of claim 43, wherein at least one of the first and second electrodes comprises at least one of Ru, Ti, Cr, Al, Au, Pd, Ni, W, Cu, Mo, Ag, In, Ir, Pb, Sn, TiAu, TiCu, TiPd, PbIn, TiW, RuN, RuO, TiN, TaN, CoSiₓ, TiSiₓ, and mixtures thereof.

48. The circuit of claim 43, wherein at least one of the first and second electrodes comprises a non-woven fabric of conducting or semiconducting nanotubes.

49. A method of forming a patterned nanotube fabric, the method comprising:
providing a substrate having a top surface, the top surface having a patterned trench;
providing a non-woven nanotube fabric over the substrate, the fabric having a first portion that substantially fills the volume defined by the patterned trench and a second portion that substantially covers the rest of the top surface of the substrate; and
substantially removing the second portion of the fabric to leave the first portions of the non-woven nanotube fabric substantially filling the volume defined by the trench.

50. The method of claim 49, wherein removing the second portion of the fabric comprises mechanically polishing the top surface of the substrate.

51. The method of claim 49, wherein the removing the second portion of the fabric comprises spraying a solvent over the top surface of the substrate.

52. The method of claim 49, further comprising exposing the fabric to reactive ions of a type and amount sufficient to increase the electrical conductivity of the fabric by a desired amount.
